(19) United States
(12) Patent Application Publication
(10) Pub. No.: US 2026/0140216 A1
(43) Pub. Date: May 21, 2026

(54) MEDICAL IMAGE PROCESSING APPARATUS, MEDICAL IMAGE PROCESSING METHOD, AND STORAGE MEDIUM

(71) Applicant: CANON MEDICAL SYSTEMS CORPORATION, Otawara-shi (JP)

(72) Inventors: Masahiro ABE, Yokohama Kanagawa (JP); Mitsuhiro BEKKU, Utsunomiya Tochigi (JP); Shohei HAMANAGA, Fukuoka Fukuoka (JP)

(73) Assignee: CANON MEDICAL SYSTEMS CORPORATION, Otawara-shi (JP)

(21) Appl. No.: 19/391,328

(22) Filed: Nov. 17, 2025

(30) Foreign Application Priority Data
Nov. 19, 2024 (JP) 2024-201440

(51) Int. Cl. G01R 33/563; G01R 33/56

(52) U.S. Cl. CPC G01R 33/56341; G01R 33/5608

(57) ABSTRACT

A medical image processing apparatus according to an embodiment is a medical image processing apparatus configured to generate a medical image based on a first complex image obtained by capturing an image of a subject, and includes an image generation unit. The image generation unit generates a second complex image obtained by removing a component of background phase from the first complex image, and generates the medical image by correcting, using noise contained in the second complex image, a pixel value of a first pixel in which a pixel value of a signal of interest representing an image of the subject is equal to or smaller than zero, in each pixel included in the second complex image.

### CROSS-REFERENCE TO RELATED APPLICATIONS

This application is based upon and claims the benefit of priority from Japanese Patent Application No. 2024-201440, filed Nov. 19, 2024, the entire contents of which are incorporated herein by reference.

### FIELD

Embodiments described herein relate generally to a medical image processing apparatus, a medical image processing method, and a storage medium.

### BACKGROUND

A diffusion-weighted image (DWI) captured by a medical image diagnosis apparatus such as a magnetic resonance imaging (MRI) apparatus has been conventionally used for diagnosing a subject. However, it has been known that, during diffusion encoding image processing, a phase variation may occur in each diffusion-weighted image due to factors such as motion, respiration, pulsation, perfusion, and magnetic field inhomogeneity. Furthermore, when a diffusion-weighted image is generated, image processing of averaging a plurality of complex images obtained by repetitive image capturing is also performed to increase a signal-to-noise ratio (S/N ratio), but since the above-described different phase variation occurs in each of the complex images used for generation of a diffusion-weighted image at this time, if the complex images are simply added, a medical image unsuitable for diagnosis may be obtained. For this reason, a diffusion-weighted image has been conventionally generated by converting the complex images to be used for the generation of a diffusion-weighted image into magnitude images, and then averaging the magnitude images. Each complex image includes a real component and an imaginary component. Thus, in calculation for converting a complex image into a magnitude image, calculation of square sum (i.e., calculation of absolute values) is performed on both the real component and the imaginary component of the complex image. At this time, Gaussian noise (noise containing positive and negative values) following a Gaussian distribution and being at a level that can be regarded as zero on average and being included in both the real component and the imaginary component of the complex image is converted, by the calculation of magnitude conversion, into Rician noise (noise containing only positive values) following a Rician distribution. Thus, if averaging of a plurality of converted magnitude images is performed to generate a diffusion-weighted image, Rician noise of each magnitude image becomes noise that generates a noise floor, and becomes a factor that causes a decrease in contrast of the diffusion-weighted image. That is, if noise contained in magnitude images remains to be Gaussian noise, by adding the magnitude images, the noise is cancelled by the positive and negative values, and the level of noise contained in a generated diffusion-weighted image becomes small. On the other hand, in a case where noise contained in magnitude images is Rician noise, the level of noise increases in the positive direction (the level of noise approaches the level of a signal of interest representing an image of a subject) by adding the magnitude images, and a difference in brightness decreases across the entire region of a generated diffusion-weighted image. Consequently, the generated diffusion-weighted image may become a whitish and blurred image overall, and thus may not be suitable for diagnosis, for example.

Thus, there has been conventionally proposed adding a real image generated from a real component, in a complex image obtained by removal of background phase. In the conventional background phase removing technique, background phase is estimated from a complex image, and only an estimated phase component is removed from phases of the complex image. Accordingly, a component of a real image of the complex image contains a signal of interest being not noise but a true signal, and Gaussian noise, and a component of an imaginary image generated from an imaginary component of the complex image contains only Gaussian noise. Thus, the component of the imaginary image of the complex image can be discarded, i.e., may not be used by being removed from the complex image when a diffusion-weighted image is generated. With this configuration, it becomes possible to simply average components of a real image of a complex image obtained by applying the background phase removing technique, and it is possible to solve an issue arising when performing averaging after the calculation of the above-described magnitude conversion in generating a diffusion-weighted image (issue that Gaussian noise is converted into Rician noise that causes a decrease in contrast).

Nevertheless, in the component of the real image included in the complex image obtained by applying the conventional background phase removing technique, the level of Gaussian noise is large, and in a pixel in which the signal intensity (level) of a signal of interest is low, the level of the signal may become equal to or smaller than the level of noise, and a value of the signal of interest (i.e., pixel value) may become equal to or smaller than zero (pixel value=“0” or a negative pixel value). An image including a pixel value equal to or smaller than zero may cause an issue that, in image processing to be subsequently performed, for example, a desirable image (here, a diffusion-weighted image) cannot be generated. Thus, a conventional proposal including a proposal related to real part addition by removal of background phase suggests performing image processing after excluding a pixel value equal to or smaller than zero from an image processing target, or after correcting the pixel value to (replacing the pixel value with) a value larger than zero. Nevertheless, the conventional proposal does not describe a value to which a pixel value equal to or smaller than zero is to be corrected. Thus, if image processing is performed after simply correcting all pixel values equal to or smaller than zero to a predetermined value larger than zero, for example, an image obtained after the image processing becomes an unnatural image. In image processing of generating, for example, a geometric mean image (isotropic diffusion weighted image (isoDWI)) as a diffusion-weighted image, pixel values may become small only along a specific motion probing gradient (MPG) axis, and an image containing an unnaturally-missing pixel is generated. In image processing of generating, for example, a diffusion tensor image as a diffusion-weighted image, because calculation of logarithm is used in the processing, in the calculation of a pixel value equal to or smaller than zero, the pixel value may become an abnormal value deviated from pixel values of surrounding pixels, and an unnatural image is obtained.

### BRIEF DESCRIPTION OF THE DRAWINGS

FIG. 1 is a diagram illustrating an example of a configuration of a medical image diagnosis apparatus including a medical image processing apparatus according to an embodiment;

FIG. 2 is a diagram illustrating an example of a functional configuration of a medical image processing apparatus according to the embodiment;

FIGS. 3A to 3C are diagrams schematically illustrating examples of images from which background phase of a complex image is removed in the medical image processing apparatus according to the embodiment;

FIGS. 4A and 4B are diagrams schematically illustrating examples of images from which background phase of a complex image is removed by calculation of conventional magnitude conversion;

FIGS. 5A and 5B are diagrams illustrating examples of images generated in the medical image processing apparatus according to the embodiment; and

FIG. 6 is a flowchart illustrating an example of a flow of processing of generating a medical image in the medical image processing apparatus according to the embodiment.

### DETAILED DESCRIPTION

A medical image processing apparatus according to an embodiment is a medical image processing apparatus configured to generate a medical image based on a first complex image obtained by capturing an image of a subject, and includes an image generation unit. The image generation unit generates a second complex image obtained by removing a component of background phase from the first complex image, and generates the medical image by correcting, using noise contained in the second complex image, a pixel value of a first pixel in which a pixel value of a signal of interest representing an image of the subject is equal to or smaller than zero, in each pixel included in the second complex image.

Various Embodiments will be described hereinafter with reference to the accompanying drawings.

The following description will be given using an example of a case where a magnetic resonance imaging (MRI) apparatus (hereinafter referred to as an “MRI apparatus”) includes a medical image processing apparatus according to an embodiment.

The MRI apparatus is a medical image processing apparatus that emits a radio frequency (RF) pulse in a state in which a strong magnetic field is applied to a subject (e.g., human body), receives, via an RF coil, an electromagnetic wave generated from a hydrogen nucleus in the body of the subject by a nuclear magnetic resonance phenomenon, and captures a tomographic image of the subject (hereinafter referred to as an “MR image”) by reconstructing a nuclear magnetic resonance signal (hereinafter referred to as an “MR signal”) that is based on the received electromagnetic waves. The MRI apparatus can also capture an MR image of a subject by reconstructing an MR signal that is based on an electromagnetic wave received via an RF coil attached to the subject. By the MRI apparatus displaying an MR image of the subject, a personnel conducting an MRI examination (a doctor, technician, etc.) can visually check whether the subject has a lesion, or the like.

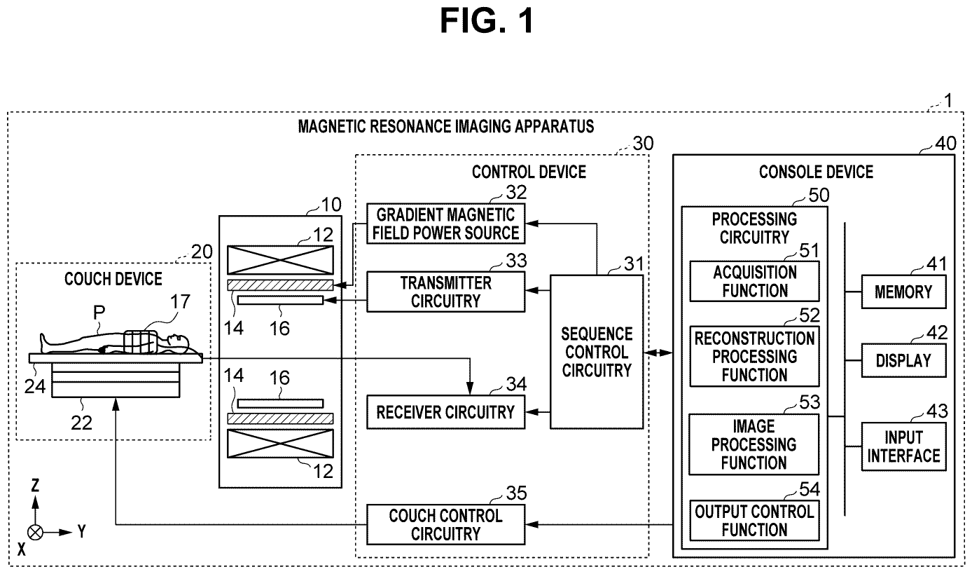

FIG. 1 is a diagram illustrating an example of a configuration of a medical image diagnosis apparatus (MRI apparatus) including a medical image processing apparatus according to an embodiment. An MRI apparatus 1 includes, for example, a gantry device 10, a couch device 20, a control device 30, and a console device 40. In the present embodiment, the description will be given assuming that the control device 30 and the console device 40 are provided separately from the gantry device 10, but some or all of the components of the control device 30 and the console device 40 may be included in the gantry device 10.

The gantry device 10 includes, for example, a static magnetic field magnet 12, a gradient magnetic field coil 14, and an RF coil 16. Furthermore, the gantry device 10 includes an RF coil 17 attachable to a subject P, for example, as a part of a component of the RF coil 16.

The static magnetic field magnet 12 is a magnet formed in a substantially cylindrical hollow shape. The static magnetic field magnet 12 generates a uniform static magnetic field in an internal space. The static magnetic field magnet 12 is, for example, a permanent magnet, a superconducting magnet, or the like. In a case where the static magnetic field magnet 12 is a superconducting magnet, the static magnetic field magnet 12 generates a static magnetic field by receiving a supply of power from a static magnetic field power source (not illustrated).

The gradient magnetic field coil 14 is a coil formed in a substantially cylindrical hollow shape. The gradient magnetic field coil 14 is arranged inside the static magnetic field magnet 12. The gradient magnetic field coil 14 is formed by combining three coils respectively corresponding to an X-axis, a Y-axis, and a Z-axis that are orthogonal to each other. The three coils respectively corresponding to directions of the axes generate gradient magnetic fields that vary in magnetic field strength along the respective axes of the X-axis, the Y-axis, and the Z-axis in an image capturing space (i.e., inside a bore) of the MRI apparatus 1 into which the subject P is introduced, by individually receiving supply of a current from a gradient magnetic field power source 32. In the present embodiment, a central axis of the gantry device 10 or a longer direction of a couchtop 24 of the couch device 20 is defined as a Y-axis direction, an axis that is orthogonal to the Y-axis direction and horizontal to a floor surface of a room in which the MRI apparatus 1 is installed is defined as an X-axis direction, and a direction that is orthogonal to the Y-axis direction and vertical to the floor surface is defined as a Z-axis direction. In the present embodiment, the Y-axis direction is the same direction as a static magnetic field.

Here, gradient magnetic fields generated by the gradient magnetic field coil 14 along the respective axes of the X-axis, the Y-axis, and the Z-axis correspond to, for example, a slice selection gradient magnetic field, a phase encoding gradient magnetic field, and a readout gradient magnetic field, respectively. The slice selection gradient magnetic field is used to determine an arbitrary image capturing cross-section in the MRI apparatus 1. The phase encoding gradient magnetic field is used to vary the phase of an MR signal in accordance with a spatial position in the MRI apparatus 1. The readout gradient magnetic field is used to vary the frequency of an MR signal in accordance with a spatial position in the MRI apparatus 1.

The RF coil 16 is a whole body coil that is housed in the gantry device 10, and configured to surround the subject P in the image capturing space. The RF coil 16 includes a transmission coil that generates a high-frequency magnetic field by receiving supply of an RF pulse from transmitter circuitry 33, and a receiving coil that receives an MR signal emitted from the subject P due to an influence of the high-frequency magnetic field. When the receiving coil of the RF coil 16 receives the MR signal, the receiving coil outputs the received MR signal to receiver circuitry 34. The RF coil 16 may include separate coils as the transmission coil and the receiving coil, or may include a single coil having both functions of transmission and receiving. In this case, the RF coil 16 may be a birdcage coil, for example.

The RF coil 17 is a local coil attached to the subject P. The RF coil 17 may have various shapes depending on each image capturing target region of the subject P (hereinafter referred to as an “image capturing region”). FIG. 1 illustrates an example of the RF coil 17 attached to the body of the subject P. The RF coil 17 receives an MR signal emitted from the subject P due to an influence of the high-frequency magnetic field generated by the RF coil 16. When the RF coil 17 receives the MR signal, the RF coil 17 outputs the received MR signal to the receiver circuitry 34. The RF coil 17 may be a wired coil that outputs the received MR signal to the receiver circuitry 34 via a cable, or may be a wireless coil that wirelessly outputs (transmits) the received MR signal to the receiver circuitry 34. FIG. 1 illustrates an example of the wired RF coil 17 that outputs the received MR signal to the receiver circuitry 34 via a coil cable connected to a coil port (not illustrated) arranged on the couchtop 24, for example. The RF coil 17 may be a coil array including a plurality of coil elements, for example. The function of the RF coil 17 may be implemented by the RF coil 16.

The couch device 20 is a device that introduces the subject P into the gantry device 10 (i.e., into the bore of the gantry device 10) by moving the couchtop 24 on which the subject P whose image is to be captured is placed. In other words, the couch device 20 is a device that moves the couchtop 24 in such a manner that an image capturing region of the subject P is located at a position desirable for image capturing in a hollow space of the static magnetic field magnet 12, the gradient magnetic field coil 14, and the RF coil 16, i.e., in a magnetic field generated in an image capturing port. The couch device 20 includes, for example, a base 22 and the couchtop 24.

By an operation of a couch driving apparatus (not illustrated) operating in accordance with a control signal output by couch control circuitry 35, the base 22 moves the couchtop 24 on which the subject P is placed, in a horizontal direction (X-axis direction and Y-axis direction) or in a vertical direction (Z-axis direction). The base 22 includes a casing movably supporting the couchtop 24. The couch driving apparatus (not illustrated) includes, for example, a motor and an actuator. The couch driving apparatus (not illustrated) may move not only the couchtop 24 but also the base 22 in the longer direction of the couchtop 24 (Y-axis direction). In a case where the gantry device 10 is configured to be movable in the Y-axis direction, the couch driving apparatus (not illustrated) may operate in such a manner as to move the gantry device 10 and introduce the subject P into the gantry device 10. In a case where both the gantry device 10 and the couchtop 24 and the base 22 are configured to be movable, the couch driving apparatus (not illustrated) may operate in such a manner as to move the gantry device 10, the couchtop 24, and the base 22 and introduce the subject P into the gantry device 10.

The couchtop 24 is a plate-like member on which the subject P is to be placed. The couchtop 24 is made of material with low conductivity (less affected by a magnetic field) such as glass fiber, for example.

The control device 30 controls operations of the gantry device 10 and the couch device 20 in accordance with control from the console device 40. The control device 30 includes, for example, sequence control circuitry 31, the gradient magnetic field power source 32, the transmitter circuitry 33, the receiver circuitry 34, and the couch control circuitry 35. The control device 30 may be provided inside the gantry device 10, or may be provided inside the console device 40.

The sequence control circuitry 31 is a sequencer that executes image capturing of the subject P by driving the gradient magnetic field power source 32, the transmitter circuitry 33, and the receiver circuitry 34 based on sequence information set by the console device 40. The sequence control circuitry 31 may be processing circuitry including a processor such as a central processing unit (CPU), for example. The sequence information is information in which a procedure for performing an image capturing process of capturing an image of the subject P in the MRI apparatus 1 is predefined. The sequence information is predefined for each image capturing process to be performed in the MRI apparatus 1. In the sequence information, for example, operations to be performed by the gradient magnetic field power source 32, the transmitter circuitry 33, and the receiver circuitry 34 when an image of the subject P is captured, and their operation timings (hereinafter referred to as “events”) are chronologically indicated. More specifically, in the sequence information, the magnitude of a current to be supplied by the gradient magnetic field power source 32 to the gradient magnetic field coil 14, a timing at which the current is to be supplied, the strength of an RF pulse to be transmitted (supplied) by the transmitter circuitry 33 to the RF coil 16, a timing at which the RF pulse is to be supplied, a timing at which the receiver circuitry 34 receives (detects) an MR signal output by the RF coil 16 or the RF coil 17, and the like are indicated as events. By sequentially executing the events indicated in the sequence information at timings that are based on a predetermined clock signal, the sequence control circuitry 31 drives the gradient magnetic field power source 32, the transmitter circuitry 33, and the receiver circuitry 34, and when the receiver circuitry 34 receives an MR signal, the receiver circuitry 34 transfers the received MR signal (more specifically, data representing the MR signal received by the receiver circuitry 34 (hereinafter referred to as “MR data”)) to the console device 40. The clock signal represents a timing that serves as a reference for an operation of capturing an image of the subject P in the MRI apparatus 1, and is generated by clock generation circuitry (not illustrated) including a clock oscillator, for example. The clock signal is supplied to each component included in the control device 30. By the sequence control circuitry 31 sequentially executing the events at timings that are based on the clock signal, the gradient magnetic field power source 32, the transmitter circuitry 33, and the receiver circuitry 34 synchronously operate.

The gradient magnetic field power source 32 individually supplies a current in the gradient magnetic field coil 14 to each of the three coils corresponding to the directions of the axes.

The transmitter circuitry 33 supplies an RF pulse to the RF coil 16. The RF pulse supplied by the transmitter circuitry 33 to the RF coil 16 is a pulse corresponding to a Larmor frequency determined based on the type of target nucleus and the strength of a magnetic field.

The receiver circuitry 34 detects an MR signal output by the RF coil 16 or the RF coil 17 and generates MR data indicating the detected MR signal. The receiver circuitry 34 generates the MR data by converting the MR signal into digital data, for example. The receiver circuitry 34 outputs the generated MR data to the sequence control circuitry 31. The sequence control circuitry 31 transfers the MR data output by the receiver circuitry 34, to the console device 40.

In accordance with control from the console device 40, the couch control circuitry 35 outputs a control signal for moving the base 22 and the couchtop 24 on which the subject P is placed, to the couch driving apparatus (not illustrated) included in the couch device 20. The couch control circuitry 35 may be provided in the gantry device 10, or may be provided in the couch device 20. In this case, the couch control circuitry 35 outputs a control signal corresponding to an input signal input from an input interface (not illustrated) by an operator of the MRI apparatus 1 such as a doctor or a technician, or a personnel conducting an MRI examination (hereinafter, will be referred to as an “MRI examination personnel”) operating an input interface (not illustrated) included in an apparatus in which the couch control circuitry 35 is provided, to the couch driving apparatus (not illustrated) included in the couch device 20.

The console device 40 controls the entire MRI apparatus 1, collects MR data, and the like. The console device 40 includes, for example, a memory 41, a display 42, an input interface 43, and processing circuitry 50.

The memory 41 is implemented by, for example, a semiconductor memory device such as a read only memory (ROM), a random access memory (RAM), or a flash memory, a hard disk drive (HDD), an optical disk, or the like. The memory 41 stores data such as, for example, MR data output by the sequence control circuitry 31, a reconstructed image (MR image) generated based on MR data, and the like. These pieces of data may be stored in an external memory with which the MRI apparatus 1 can communicate, instead of the memory 41 (or in addition to the memory 41). The external memory is controlled by a cloud server that manages the external memory, by a network attached storage (NAS) or the cloud server receiving read/write requests, for example. The external memory is implemented by a system called a picture archiving and communication system (PACS), for example. The PACS is a medical image management system that systematically stores medical images captured by various medical image diagnosis apparatuses, and the like.

The display 42 displays various types of information. For example, the display 42 displays a medical image generated by the processing circuitry 50, a graphical user interface (GUI) image for receiving various operations performed by an MRI examination personnel, and the like. The display 42 is, for example, a liquid crystal display (LCD), a cathode ray tube (CRT) display, an organic electroluminescence (EL) display, or the like. The display 42 may be provided in the gantry device 10. The display 42 may be a desktop type display, or may be a display device (e.g., table terminal) that can wirelessly communicate with a main body portion of the console device 40.

The input interface 43 receives various input operations performed by an MRI examination personnel, and outputs an electric signal indicating the content of the received input operations to the processing circuitry 50. For example, the input interface 43 receives input operations of a collection condition to be used when MR data is collected, a generation condition to be used when MR data is generated, a reconstruction condition to be used when a reconstructed image is reconstructed, and an image processing condition to be used when a postprocessed image is generated from a reconstructed image. The input interface 43 is implemented by, for example, a mouse, a keyboard, a touch panel, a trackball, a switch, a button, a joystick, a camera, an infrared sensor, a microphone, or the like. In a case where the input interface 43 is a touch panel, the display 42 may be formed integrally with the input interface 43. The input interface 43 may be provided in the gantry device 10. The input interface 43 may be implemented by a display device (e.g., tablet terminal) that can wirelessly communicate with the main body portion of the console device 40. In this specification, the input interface 43 is not limited to an input interface including a physical operational component such as a mouse or a keyboard described above. For example, electric signal processing circuitry that receives an electric signal corresponding to an input operation from an external input device provided separately from the console device 40, and outputs the received electric signal to the processing circuitry 50 is also included in the examples of the input interface 43.

The processing circuitry 50 controls operations of the entire MRI apparatus 1. The processing circuitry 50 sets sequence information in the sequence control circuitry 31. For example, in a case where a diffusion-weighted image (DWI) of the subject P is to be captured by the MRI apparatus 1, the processing circuitry 50 sets sequence information corresponding to an image capturing process of the DWI in the sequence control circuitry 31. The processing circuitry 50 executes, for example, an acquisition function 51, a reconstruction processing function 52, an image processing function 53, an output control function 54, and the like. For example, the processing circuitry 50 implements these functions by a hardware processor, which is included in a computer device, executing a program (software) stored in the memory 41 that is a storage device (storage circuitry).

The hardware processor refers to circuitry such as, for example, a CPU, a graphics processing unit (GPU), a large scale integration (LSI), a system-on-chip (SOC), an application specific integrated circuit (ASIC), or a programmable logic device (e.g., a simple programmable logic device (SPLD) or a complex programmable logic device (CPLD), a field programmable gate array (FPGA)). Instead of storing a program in the memory 41, the program may be directly incorporated in circuitry of the hardware processor. In this case, the hardware processor implements a function by reading and executing the program installed in the circuitry. The hardware processor is not limited to a processor formed as a single piece of circuitry, and may be formed by combining a plurality of pieces of independent circuitry into one hardware processor to implement each function. Each function may also be implemented by integrating a plurality of components into one hardware processor. Each function may also be implemented by incorporating a plurality of components into one dedicated LSI. Here, the program (software) may be preliminarily stored in a storage device that constitutes the memory 41, such as a semiconductor memory device such as a ROM, a RAM, or a flash memory, or an HDD, the storage device including a non-transitory storage medium, or may be stored in a detachable storage medium, i.e., a non-transitory storage medium, such as a digital versatile disc (DVD) or a compact disk read only memory (CD-ROM), and by the storage medium being mounted on a drive device included in the console device 40, the program may be installed in a storage device included in the console device 40. The program (software) may be preliminarily downloaded from another computer device via a network (not illustrated) and installed in a storage device included in the console device 40.

Each component included in the console device 40 or the processing circuitry 50 may be implemented by a plurality of hardware components in a distributed manner. The processing circuitry 50 may be implemented by a processing apparatus capable of communicating with the console device 40, instead of being implemented as a component included in the console device 40. The processing apparatus is, for example, a work station connected with a single MRI apparatus, or an apparatus (e.g., cloud server) that is connected to a plurality of MRI apparatuses and collectively executes processing equivalent to that of the processing circuitry 50 to be described below. In other words, a configuration of the present embodiment can also be implemented as an MRI examination system (medical diagnosis system) in which an MRI apparatus and another processing apparatus are connected via a network (not illustrated).

The acquisition function 51 acquires MR data transferred by the sequence control circuitry 31. The MR data is obtained by converting an MR signal into digital data by the receiver circuitry 34. The acquisition function 51 stores the acquired MR data in the memory 41.

The reconstruction processing function 52 generates a reconstructed image by performing predetermined reconstruction processing on the MR data acquired by the acquisition function 51 (MR data stored in the memory 41). The reconstruction processing function 52 generates a reconstructed image by arranging MR data in two or three dimensions corresponding to a slice selection gradient magnetic field, a phase encoding gradient magnetic field, and a readout gradient magnetic field, for example, and then performing reconstruction processing that uses Fourier transform or the like. The reconstruction processing function 52 stores the generated reconstructed image in the memory 41.

The image processing function 53 generates an MR image to be presented to an MRI examination personnel, by performing predetermined image processing on the reconstructed image stored in the memory 41, based on an input operation received via the input interface 43. MR images generated by the image processing function 53 may include, for example, a T1-weighted image (WI), a T2-weighted image, a proton density weighted image, a fluid attenuated inversion recovery (FLAIR) image, a T2*-weighted image, a susceptibility weighted image (SWI), a diffusion-weighted image (DWI), an MR angiography (MRA) image, and an MR perfusion (MRP) image. The image processing function 53, in particular, generates a more suitable diffusion-weighted image by removing background phase from an original reconstructed image (a complex signal image, hereinafter referred to as a “complex image”) when generating a diffusion-weighted image. Details of image processing performed at the time will be described below. The image processing function 53 stores the converted MR image in the memory 41.

The image processing function 53 is an example of a “medical image processing apparatus”. The complex image is an example of a “first complex image”, and the diffusion-weighted image is an example of a “medical image”.

The output control function 54 controls a display mode on the display 42, for example. The output control function 54 outputs an MR image generated by the image processing function 53 and stored in the memory 41, to the display 42 and displays the MR image thereon. An MRI examination personnel can thereby visually check the MR image displayed on the display 42 and perform diagnosis or examination to determine whether the subject P has a lesion, or the like. The output control function 54 may transmit an MR image to a tablet terminal, for example, that is connected with the main body portion of the console device 40 via a network (not illustrated), and display the MR image on a display device. The output control function 54 may display a GUI image for receiving various operations to be performed by an MRI examination personnel, and the like.

### [Functional Configuration of Medical Image Processing Apparatus]

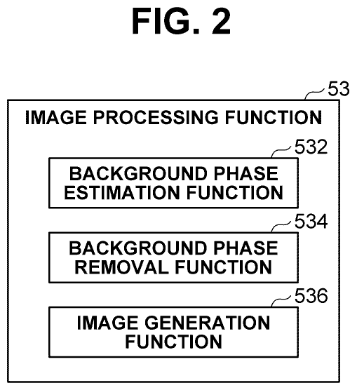

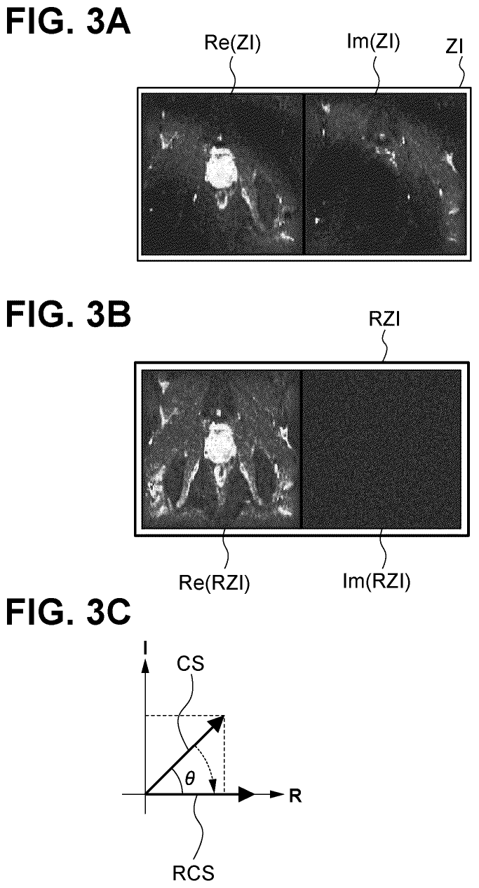

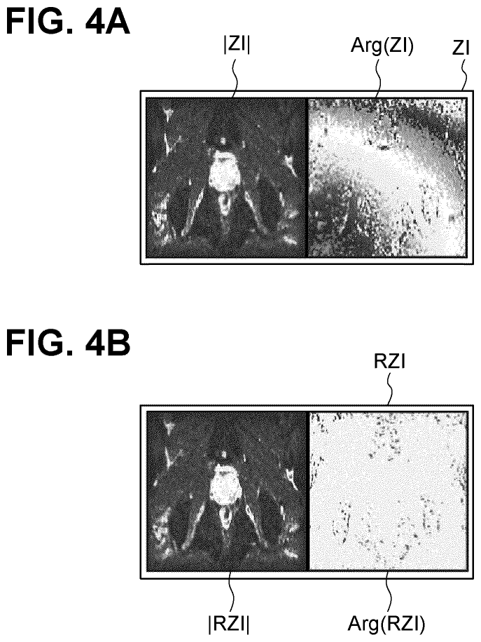

Next, configurations and operations for implementing a function of performing image processing for generating a diffusion-weighted image in the image processing function 53 will be described. FIG. 2 is a diagram illustrating an example of a functional configuration of the medical image processing apparatus (the image processing function 53) according to the embodiment. FIGS. 3A to 3C are diagrams schematically illustrating examples of images from which background phase of a complex image is removed in the medical image processing apparatus (the image processing function 53) according to the embodiment. The image processing function 53 executes, for example, a background phase estimation function 532, a background phase removal function 534, an image generation function 536, and the like. FIGS. 4A and 4B are diagrams schematically illustrating examples of images from which background phase of a complex image is removed by calculation of conventional magnitude conversion. FIGS. 4A and 4B are diagrams for comparing image processing executed by the image processing function 53 and image processing executed by the conventional magnitude conversion. In the following description, each function executed by the image processing function 53 illustrated in FIG. 2 will be described while appropriately referring to the examples of an image illustrated in FIGS. 3A to 3C, and further comparing the examples with examples of conventional images illustrated in FIGS. 4A and 4B.

Here, in the following description, it is assumed that the memory 41 stores a reconstructed image serving as the basis for a diffusion-weighted image generated by the reconstruction processing function 52, i.e., a plurality of complex images for generating a diffusion-weighted image. Each of the complex images is a medical image captured by the MRI apparatus 1 while varying the strength and the direction of a gradient magnetic field. That is, each of the complex images is a medical image in which a diffusional motion of water molecules (i.e., the strength at which water molecules are diffused by Brownian motion) is regarded as a change in phase, by transmitting (supplying) an RF pulse with the intensity of a motion probing gradient (MPG) in a direction of the MPG in the MRI apparatus 1. More specifically, each of the complex images is a medical image obtained by causing the transmitter circuitry 33 to transmit (supply) an RF pulse with the MPG intensity from the RF coil 16 in the MPG direction in a state in which the sequence control circuitry 31 generates a magnetic field in an image capturing port (bore) of the gantry device 10 in accordance with an event indicated in sequence information corresponding to an image capturing process of a diffusion-weighted image, in the MRI apparatus 1, and causing the receiver circuitry 34 to receive (detect) an MR signal output by the RF coil 16 or the RF coil 17. Each of the complex images has a real component and an imaginary component.

FIG. 3A illustrates an example of a complex image on which the image processing function 53 performs image processing. In FIG. 3A, a complex image ZI divided into an image of the real component (hereinafter referred to as “real image”) Re(ZI) and an image of the imaginary component (hereinafter referred to as an “imaginary image”) Im(ZI) is illustrated. Here, both the real image Re(ZI) and the imaginary image Im(ZI) include a signal of interest indicating an image of the subject P (true signal not being noise), and Gaussian noise following a Gaussian distribution (noise containing positive and negative values). The Gaussian noise is noise at a level that can be regarded as zero on average. Furthermore, the real part image Re(ZI) and the imaginary part image Im(ZI) include phase variations that occur during image capturing.

The complex image ZI is an example of a “first complex image”. The Gaussian noise is an example of “noise” and “noise containing positive and negative values”.

In the image processing executed by conventional magnitude conversion, each complex image is converted into a magnitude. The method of magnitude conversion of a complex image is a known method. In the following description, an image representing a complex image in terms of magnitude is referred to as a “magnitude image”, and an image representing a complex image in terms of phase is referred to as a “phase image”.

FIG. 4A illustrates an example of images representing the complex image ZI illustrated in FIG. 3A in terms of magnitude and phase. In FIG. 4A, the complex image ZI divided into a magnitude image |ZI| and a phase image Arg(ZI) is illustrated. Here, the magnitude image |ZI| includes a signal of interest and Rician noise (noise containing only positive values) following a Rician distribution that has been converted from Gaussian noise through magnitude conversion. Rician noise generates a noise floor and becomes a factor causing a reduction in contrast of a diffusion-weighted image to be generated.

The background phase estimation function 532 acquires each complex image used for generating a diffusion-weighted image from the memory 41, performs smoothing on each acquired complex image, and calculates (estimates) the background phase included in the complex image based on an image computed through smoothing. A background phase estimation method to be used in the background phase estimation function 532 is a known method. The background phase calculation (estimation) in the background phase estimation function 532 may be performed using a technique of artificial intelligence (AI), for example. Background phase is information indicating a phase component of the smoothed complex image. The background phase estimation function 532 outputs an image representing the estimated background phase (hereinafter referred to as a “background phase image”) to the background phase removal function 534.

Based on the background phase image output by the background phase estimation function 532, the background phase removal function 534 removes background phase from a complex signal of each complex image acquired from the memory 41. More specifically, by applying a coefficient calculated based on a complex conjugate of the background phase and the magnitude of the background phase image to the complex signal, the background phase is removed, and it is possible to express, by real components, all signal intensities (levels) of a signal of interest, represented by a real component and an imaginary component in the complex signal. The background phase removal function 534 outputs each complex image from which the background phase has been removed (hereinafter referred to as a “background-phase-removed complex image”) to the image generation function 536.

FIG. 3B illustrates an example of a complex image RZI obtained by removing background phase from the complex image ZI in the background phase removal function 534. In FIG. 3B, a background-phase-removed complex image RZI divided into a real image Re(RZI) and an imaginary image Im(RZI) is illustrated. The real image Re(RZI) includes a signal of interest and a Gaussian noise, and the imaginary image Im(RZI) includes only Gaussian noise. That is, the real image Re(RZI) and the imaginary image Im(RZI) become images obtained by removing the background phase, which is respectively included in the real image Re(ZI) and the imaginary image Im(ZI). Thus, by simply averaging the complex image RZI, it is possible to reduce the level of Gaussian noise (e.g., to a level that can be regarded as substantially zero).

The complex image RZI is an example of a “second complex image”. The real image Re(RZI) is an example of a “second component image”, and the imaginary image Im(RZI) is an example of a “first component image”.

FIG. 4B illustrates an example of images representing the complex image RZI illustrated in FIG. 3B in terms of magnitude and phase. In FIG. 4B, the complex image RZI divided into a magnitude image |RZI| and a phase image Arg(RZI) is illustrated. Here, as can be seen from comparison between the complex image ZI illustrated in FIG. 4A and the complex image RZI illustrated in FIG. 4B, the background-phase-removed magnitude image |RZI| does not change greatly from the magnitude image |ZI|. Then, the background-phase-removed phase image Arg(RZI) is a substantially uniform image although background phase included in the phase image Arg(ZI) is removed and noise components remain in some degree.

FIG. 3C illustrates an example in which a concept of removing background phase from a complex signal of the complex image ZI is represented on a complex plane of the complex signal. In FIG. 3C, on the complex plane represented by a real axis R and an imaginary axis I, the signal intensity (level) of a signal of interest indicated by a complex signal CS is illustrated as the length of an arrow having a background phase component θ. Then, FIG. 3C illustrates that, by the background phase removal function 534 removing the background phase (i.e., setting the background phase component θ to “0°” by rotating the arrow), it is possible to convert the complex signal CS into a complex signal RCS in which all signal intensities (levels) of the signal of interest are represented as the length of the arrow on the real axis R.

The configuration of the image processing function 53 that has been described so far, i.e., the configurations of the background phase estimation function 532 and the background phase removal function 534 included in the image processing function 53, is similar to a conventional configuration in which real part addition by removal of background phase is performed. Thus, by discarding the imaginary image Im(RZI) including only Gaussian noise, from the complex image RZI illustrated in FIG. 3B (without using the imaginary image Im(RZI)), and performing averaging on the real image Re(RZI), the image processing function 53 can also generate a diffusion-weighted image similar to that by a conventional technique. In other words, with the configurations described above, the image processing function 53 can generate a diffusion-weighted image similar to that by the conventional technique without converting Gaussian noise contained in the complex image ZI into Rician noise that causes a reduction in contrast.

The conventional configuration in which real part addition by removal of background phase is performed in the image processing function 53 is not limited to the above-described configurations of the background phase estimation function 532 and the background phase removal function 534, and may be any configuration as long as the configuration is a configuration of generating a complex image equivalent to the complex image RZI illustrated in FIG. 3B.

In the image processing function 53, as compared with the conventional configuration in which real part addition by removal of background phase is performed, the image generation function 536 that generates a diffusion-weighted image by averaging complex images is different.

The image generation function 536 generates a diffusion-weighted image by correcting a background-phase-removed complex image output by the background phase removal function 534. More specifically, the image generation function 536 generates a diffusion-weighted image while correcting, using the signal intensity of a pixel of an imaginary image, a pixel in which the signal intensity (level) of a signal of interest is lower than a predetermined level in a real image of the background-phase-removed complex image. At this time, the image generation function 536 corrects a pixel value of a pixel in which the signal intensity (level) of a signal of interest, i.e., a pixel value, is equal to or smaller than zero (pixel value=“0” or a negative pixel value), among pixels included in a background-phase-removed real image, by replacing the pixel value with a pixel value of a pixel that is at the same position and constitutes a background-phase-removed imaginary image. That is, the image generation function 536 corrects a real image of a background-phase-removed complex image using a pixel value of a pixel of an imaginary image (background-phase-removed imaginary image including only Gaussian noise) that is conventionally discarded. The image generation function 536 can accordingly improve a state of noise contained in a diffusion-weighted image to be generated, and generate a medical image that appears more natural and does not cause a sense of incongruity.

The image generation function 536 is an example of an “image generation unit”. The pixel in which the signal intensity (level=pixel value) of a signal of interest is equal to or smaller than zero (pixel value=“0” or a negative pixel value), among pixels included in a background-phase-removed real image, is an example of a “first pixel”.

Here, a method of generating a diffusion-weighted image while correcting a pixel value in the image generation function 536 will be described in more detail. In the following description, the number of complex images (background-phase-removed complex images) to be averaged when a diffusion-weighted image is generated, i.e., the number of times the background-phase-removed complex images are added, is assumed to be N (where N is a natural number equal to or larger than 2).

The image generation function 536 performs the calculation of an average value Avg of pixel values of a signal of interest (including Gaussian noise) of a complex image Z (background-phase-removed complex image) for each MPG intensity bval and each MPG direction bvec. The calculation of the average value Avg is represented by Equation (1) below.

$${Avg}_{bval , bvec} = \frac{1}{N} {\sum }_{i = 1}^{N} Re ( {Z}_{nex = i , bval , bvec} ) \qquad [ Equation 1 ]$$

In Equation (1) described above, nex denotes the number of excitations (i.e., the number of image acquisitions) performed when a plurality of complex images Z is captured, and denotes the number of complex images Z to be averaged to generate a diffusion-weighted image. In Equation (1) described above, Re(Z) denotes a value of a real component of the complex image Z. That is, Re(Z_{nex=i,bval,bvec}) denotes the value of a real component included in a complex image Z with the MPG intensity bval and the MPG direction bvec for the i-th acquisition out of the number of image acquisitions nex. Accordingly, in Equation (1) described above, an average value Avg_{bval,bvec} is calculated by averaging real components Re with the same MPG intensity bval and MPG direction bvec in a plurality of complex images Z from the first to Nth acquisitions out of the numbers of image acquisitions nex. In other words, the average value Avg is an average of pixel values of pixels at the same position in the plurality of complex images Z.

The pixels at the same position in the plurality of complex images Z are examples of the “first pixel”. The average value Avg is an example of an “average value”.

Here, a case where the number of MPG axes is “3” (e.g., three axes corresponding to the X axis, the Y axis, and the Z axis illustrated in FIG. 1), the number of image acquisitions nex is “2”, and the MPG intensity bval of the complex image Z=1000 [s/mm²] will be considered. In this case, the image generation function 536 calculates the average value Avg as represented by Equation (2) below.

$$\begin{matrix}[ Equation 2 ] & \\ {Avg}_{bval - 1000 , bvec - {v}_{1}} = \frac{1}{2} \{ Re ( {Z}_{nex - 1 , bval - 1000 , bvec - {v}_{1}} ) + Re ( {Z}_{nex - 2 , bvel - 1000 , bvec - {v}_{1}} ) \} & ( 2 )\end{matrix}$$

On the other hand, the image generation function 536 performs calculation of a correction value Corr for correcting the average value Avg for each MPG intensity bval using an imaginary component Im of the complex image Z, i.e., Gaussian noise. The calculation of the correction value Corr is represented by Equation (3) below.

$$\begin{matrix}[ Equation 3 ] & \\ {Corr}_{bval} = Smooth ( \frac{1}{V} {\sum }_{j = 1}^{V} \vert \frac{1}{N} {\sum }_{i = 1}^{N} Im ( {Z}_{nex = i , bval , bvec = {v}_{j}} ) \vert ) & ( 3 )\end{matrix}$$

In Equation (3) described above, V denotes an MPG direction, i.e., the number of MPG axes, and Im(Z) denotes a value of an imaginary component of the complex image Z. In Equation (3) described above, the correction value Corr_{bval} is calculated by averaging absolute values obtained by averaging values (Im(Z_{nex=i,bval,bvec=vj})) of imaginary components included in the complex image Z with the MPG intensity bval and the MPG direction bvec=vj for the i-th acquisition out of the number of image acquisitions nex, from the first to Nth acquisitions out of the number of image acquisitions nex, by the number of MPG axes along which the complex image Z has been captured, and further performing smoothing. In the calculation of the correction value Corr_{bval}, the smoothing may be omitted. That is, the correction value Corr may be a value obtained by averaging absolute values obtained by averaging noise values of Gaussian noise of pixels at the same position corresponding to the average value Avg of a signal of interest in a plurality of complex images Z, by the number of MPG axes.

The noise value of Gaussian noise of the pixels at the same position corresponding to the average value Avg of the signal of interest in the plurality of complex images Z is an example of a “noise value of noise indicated by a second pixel”. The correction value Corr is an example of a “correction value”. The calculation of the correction value Corr by Equation (3) described above is an example of “calculation of a correction value”.

Here, a case where the number of MPG axes is “3” (e.g., three axes corresponding to the X axis, the Y axis, and the Z axis illustrated in FIG. 1), the number of image acquisitions nex is “2”, and the MPG intensity bval of the diffusion-weighted image is “1000” will be considered. In this case, the image generation function 536 calculates the correction value Corr as represented by Equation (4) below.

$$\begin{matrix}[ Equation 4 ] & \\ {Corr}_{bval = 1000} = Smooth [ \frac{1}{3} \{ \begin{matrix}\vert \frac{Im ( {Z}_{nex = 1 , bval = 1000 , bvex = {v}_{1}} ) + Im ( {Z}_{nex = 2 , bval = 1000 , bvec = {v}_{1}} )}{2} \vert + \\ \vert \frac{Im ( {Z}_{nex = 1 , bval = 1000 , bvex = {v}_{2}} ) + Im ( {Z}_{nex = 2 , bval = 1000 , bvec = {v}_{2}} )}{2} \vert + \\ \vert \frac{Im ( {Z}_{nex = 1 , bval = 1000 , bvex = {v}_{3}} ) + Im ( {Z}_{nex = 2 , bval = 1000 , bvec = {v}_{3}} )}{2} \vert\end{matrix} \} ] & ( 4 )\end{matrix}$$

Then, based on the average value Avg calculated by Equation (1) described above and the correction value Corr calculated by Equation (3) described above, the image generation function 536 corrects a background-phase-removed complex image output by the background phase removal function 534, for each MPG intensity bval and each MPG direction bvec. More specifically, the image generation function 536 compares the average value Avg and the correction value Corr, and sets the larger one (not smaller one) as an average value Avg′ being the corrected average value Avg in the complex image Z (background-phase-removed complex image). The calculation of the average value Avg′ is represented by Equation (5) below.

$$\begin{matrix}[ Equation 5 ] & \\ {Avg}_{bval , bvec}^{′} = max ( {Agv}_{bval , bvec} , {Corr}_{bval} ) & ( 5 )\end{matrix}$$

The average value Avg′ is an example of a corrected “pixel value of a first pixel”.

In this manner, in a case where the signal intensity (level) of a signal of interest in the real component of the complex image Z is lower than the signal intensity (level) of Gaussian noise at the same position of the imaginary component, the image generation function 536 generates a diffusion-weighted image while correcting the signal intensity (level) by replacing the signal intensity (level) with the signal intensity (level) of Gaussian noise of the imaginary component. That is, in a case where a pixel value of each pixel included in a background-phase-removed real image is lower than a noise value of Gaussian noise of a background-phase-removed imaginary image, the image generation function 536 generates the diffusion-weighted image while correcting the pixel value of the pixel by replacing the pixel value with the noise value of Gaussian noise at the same position. Consequently, the diffusion-weighted image generated by the image generation function 536 becomes a medical image that appears natural and does not cause a sense of incongruity as compared with a diffusion-weighted image generated conventionally by averaging complex images on which real part addition by removal of background phase has been performed.

In the above-described example, an example of calculation of the average value Avg and the correction value Corr has been described in consideration of the case where the number of MPG axes is three corresponding to the X axis, the Y axis, and the Z axis illustrated in FIG. 1. Nevertheless, in the MRI apparatus 1, for example, by controlling the direction of an axis of a gradient magnetic field generated by the gradient magnetic field coil 14, it is possible to make the number of MPG axes larger than three. The calculation of the average value Avg and the correction value Corr to be performed in this case can be easily considered from the above-described calculation method in accordance with the number of MPG axes, and can be similarly performed. Accordingly, the detailed description of a method of the calculation of the average value Avg and the correction value Corr to be performed in the case where the number of MPG axes is larger than three will be omitted.

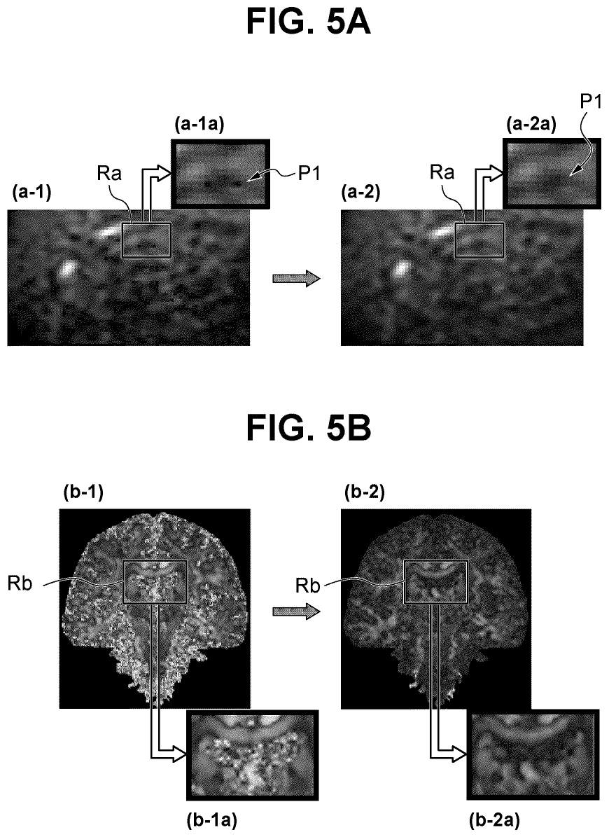

Here, an example of an image to be generated by the image generation function 536 will be described. FIGS. 5A and 5B are diagrams illustrating examples of images generated in the medical image processing apparatus according to the embodiment (the image processing function 53, more specifically, the image generation function 536). In FIG. 5A, an example of a geometric mean image, i.e., isotropic diffusion weighted image (isoDWI), generated as a diffusion-weighted image by the image generation function 536 is illustrated. In FIG. 5B, an example of a diffusion tensor image calculated from a diffusion-weighted image by the image generation function 536 is illustrated. The geometric mean image and the diffusion tensor image are MR images (medical images) that can be generated based on respective similar background-phase-removed complex images. In FIGS. 5A and 5B, for comparison, images generated conventionally based on a background-phase-removed complex image on which real part addition by removal of background phase has been performed (see the complex image RZI illustrated in FIG. 3B), and images generated by the image generation function 536 while correcting the background-phase-removed complex images are illustrated. In the following description, a geometric mean image generated based on an uncorrected background-phase-removed complex image will be referred to as an “unimproved geometric mean image”, and a geometric mean image generated while correcting a background-phase-removed complex image will be referred to as an “improved geometric mean image”. Further, a diffusion tensor image generated based on an uncorrected background-phase-removed complex image will be referred to as an “unimproved diffusion tensor image”, and a diffusion tensor image generated while correcting a background-phase-removed complex image will be referred to as an “improved diffusion tensor image”.

First, geometric mean images illustrated in FIG. 5A will be described. An image (a-1) of FIG. 5A illustrates an example of an unimproved geometric mean image and an image (a-2) of FIG. 5A illustrates an example of an improved geometric mean image. For the ease of description, the geometric mean images illustrated in the image (a-1) and in the image (a-2) of FIG. 5A are images obtained by enlarging the same position in the geometric mean images of an unimproved geometric mean image generated based on an uncorrected background-phase-removed complex image, and an improved geometric mean image generated while correcting a background-phase-removed complex image. Then, in an image (a-1a) of FIG. 5A- and an image (a-2a) of FIG. 5A, regions Ra at the same position is further illustrated in an enlarged manner. As can be seen from a comparison between the unimproved geometric mean image illustrated in the image (a-1) of FIG. 5A and the improved geometric mean image illustrated in the image (a-2) of FIG. 5A, or between the enlarged image of the region Ra illustrated in the image (a-1a) of FIG. 5A and the enlarged image of the region Ra illustrated in the image (a-2a) of FIG. 5A, in the improved geometric mean image, the state of noise contained in the images is improved, and medical images that appear natural and do not cause a sense of incongruity compared to the unimproved geometric mean image are obtained. More specifically, in the uncorrected background-phase-removed complex image, pixels with pixel values equal to or smaller than zero among pixels included in the generated unimproved geometric mean image become an unnaturally-missing state (black) as in a pixel P1 illustrated in the image (a-1a) of FIG. 5A, for example. In contrast to this, in the improved geometric mean image, because pixels with pixel values equal to or smaller than zero are corrected using pixel values at the same positions of an imaginary image containing only Gaussian noise that is to be conventionally discarded (see the imaginary image Im(RZI) illustrated in FIG. 3B), i.e., the signal intensity (level) of Gaussian noise, the pixels do not become the unnaturally-missing state as in a pixel P1 illustrated in the image (a-2a) of FIG. 5A, for example. Moreover, in the improved geometric mean image, since the pixel values equal to or smaller than “0” are corrected by replacing the pixel values with noise values of Gaussian noise, the correction is not excessively executed. Consequently, in the improved geometric mean image illustrated in the image (a-2) of FIG. 5A, a medical image that appears natural and does not cause a sense of incongruity as compared with the unimproved geometric mean image illustrated in the image (a-1) of FIG. 5A is obtained.

Subsequently, diffusion tensor images illustrated in FIG. 5B will be described. An image (b-1) of FIG. 5B illustrates an example of an unimproved diffusion tensor image, and an image (b-2) of FIG. 5B illustrates an example of an improved diffusion tensor image. In an image (b-1a) of FIG. 5B and in an image (b-2a) of FIG. 5B, regions Rb at the same position in the unimproved diffusion tensor image and the improved diffusion tensor image are illustrated in an enlarged manner. A diffusion tensor image is a medical image in which directions in which water molecules are diffusion-restricted are represented by, for example, color-coding a left-right direction of the diffusion tensor image illustrated in FIG. 5B into “red”, a front-back direction (depth direction) into “green”, and an up-down direction into “blue”, and a range of the region Rb includes a part in which an image of “water” is mainly captured. The part of the diffusion tensor image in which an image of “water” is mainly captured is a pixel in which the level of the signal intensity (level) of a signal of interest is low, i.e., a pixel in which a pixel value is likely to be equal to or smaller than zero or a negative value). Nevertheless, as can be seen from the unimproved diffusion tensor image illustrated in the image (b-1) of FIG. 5B or an enlarged image of the region Rb illustrated in the image (b-1a) of FIG. 5B, in the unimproved diffusion tensor image, an image in which a pixel adjacent to the part in which an image of “water” is mainly captured has a different color, i.e., an unnatural image in which continuity of diffusion restriction is impaired, is obtained. This is because image processing for generating a diffusion tensor image includes calculation of a logarithm not expecting a negative pixel value, and by the calculation of logarithm, a noise value equal to or smaller than zero of Gaussian noise contained in the uncorrected background-phase-removed complex image (more specifically, a background-phase-removed real image), or a negative noise value becomes an abnormal value deviated from pixel values of surrounding pixels, and indicate various directions. In contrast to this, as can be seen from the improved diffusion tensor image illustrated in the image (b-2) of FIG. 5B or an enlarged image of the region Rb illustrated in the image (b-2a) of FIG. 5B, in the improved diffusion tensor image, the part in which an image of “water” is mainly captured becomes a dark state, and a medical image that appears more natural and in which continuity of restricted diffusion is observed is obtained. This is because, in the improved diffusion tensor image, since pixels with pixel values equal to or smaller than zero are corrected by the correction value Corr of a noise value of Gaussian noise that has become a positive value by obtaining an absolute value in the calculation of Equation (3) described above, even if the calculation of logarithm is performed in the image processing for generating a diffusion tensor image, the pixel values do not become abnormal values deviated from pixel values of the surrounding pixels.

In this manner, the image generation function 536 generates a diffusion-weighted image (in the above-described example, an isoDWI or a diffusion tensor image) by averaging background-phase-removed complex images output by the background phase removal function 534 while performing correction thereon. The image generation function 536 outputs the generated diffusion-weighted image to the output control function 54. With this configuration, in the MRI apparatus 1, the output control function 54 displays a diffusion-weighted image output by the image generation function 536, i.e., the image processing function 53, on the display 42 and presents the diffusion-weighted image to an MRI examination personnel.

### [Processing of Medical Image Processing Apparatus]

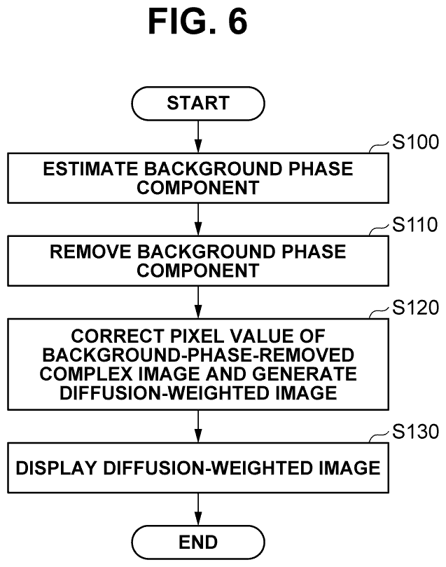

Next, a flow of image processing of generating a diffusion-weighted image in the image processing function 53 will be described. FIG. 6 is a flowchart illustrating an example of a flow of processing of generating a medical image (diffusion-weighted image) in the medical image processing apparatus (the image processing function 53) according to the embodiment. In the following description, a plurality of complex images for generating a diffusion-weighted image that has been generated by the reconstruction processing function 52 is stored in the memory 41.

When the processing of generating a diffusion-weighted image is started in the image processing function 53, in step S100, the background phase estimation function 532 acquires complex images to be used for generating a diffusion-weighted image from the memory 41, and calculates (estimates) background phase to be removed from the complex images, based on an image obtained by performing smoothing and calculation on the acquired complex images. The background phase estimation function 532 outputs a background phase image representing the calculated (estimated) background phase to the background phase removal function 534.

Next, in step S110, the background phase removal function 534 removes the background phase from a complex signal of each complex image acquired from the memory 41, based on the background phase image output by the background phase estimation function 532. The background phase removal function 534 outputs each background-phase-removed complex image to the image generation function 536.

Next, in step S120, the image generation function 536 generates a diffusion-weighted image by averaging pixel values of the background-phase-removed complex image output by the background phase removal function 534 while correcting the pixel values. The image generation function 536 stores the generated diffusion-weighted image in the memory 41.

In step S130, the output control function 54 displays the diffusion-weighted image generated by the image processing function 53 (the image generation function 536) and stored in the memory 41 on the display 42, and presents the diffusion-weighted image to an MRI examination personnel. Then, the MRI apparatus 1 (the image processing function 53 included in the processing circuitry 50) ends the processing of this flowchart.

With such a configuration and processing, the image processing function 53 in the processing circuitry 50 included in the MRI apparatus 1 generates a complex image (background-phase-removed complex image) similarly to the conventional configuration in which real part addition by removal of background phase is performed. Then, the image processing function 53 generates a diffusion-weighted image while correcting, using a pixel value of a pixel in an imaginary image that is conventionally discarded (background-phase-removed imaginary image containing only Gaussian noise), a pixel in which the signal intensity (level) of a signal of interest is lower than a predetermined level in a real image (background-phase-removed real image). With this configuration, in the MRI apparatus 1 including the image processing function 53 as a medical image processing apparatus, it is possible to improve the state of noise contained in each original complex image generated by averaging, and generate a diffusion-weighted image that appears more natural and does not cause a sense of incongruity compared to a diffusion-weighted image conventionally generated by averaging complex images on which real part addition by removal of background phase has been performed. An MRI examination personnel can accordingly visually check a diffusion-weighted image (MR image) displayed on the display 42, and naturally perform diagnosis or examination to determine whether the subject P has a lesion, or the like.

### [Another Example of Correction Value]

In the above-described example, the correction value Corr for correcting (replacing) a pixel with a low signal intensity (level) of a signal of interest, in a real component of the complex image Z, is calculated by Equation (3) described above for each MPG intensity bval. That is, the correction value Corr is calculated by averaging absolute values obtained by averaging noise values of Gaussian noise (values of an imaginary component) of pixels at the same position corresponding to the average value Avg of the signal of interest in a plurality of complex images Z, by the number of MPG axes. On the other hand, in order to calculate the correction value Corr, it is necessary to calculate an absolute value of a noise value of Gaussian noise being noise containing positive and negative values. This is because, if a result of averaging noise values of Gaussian noise becomes a negative value, a pixel with the negative value becomes a factor that makes a diffusion-weighted image an unnatural image. Nevertheless, the calculation of an absolute value of a noise value of Gaussian noise that is performed to calculate the correction value Corr may be performed at any timing. That is, a timing at which a calculation result of a positive value is obtained by the calculation of an absolute value may be any timing in the calculation of the correction value Corr. For example, the calculation of the correction value Corr may be performed as represented by Equation (6) described below or Equation (7) described below. When a correction value Corr_{bval} is calculated by Equation (6) described below or Equation (7) described below, smoothing may be omitted, but for the sake of ease of comparison with Equation (3) described above, in Equation (6) described below and Equation (7) described below, an example in a case where smoothing is performed is described. Nevertheless, in the following description, for the sake of ease of description of the timing of the calculation of an absolute value, the description of smoothing is omitted.

$$\begin{matrix}[ Equation 6 ] & \\ {Corr}_{bval} = Smooth ( \frac{1}{V} {\sum }_{j = 1}^{V} \frac{1}{N} {\sum }_{i = 1}^{N} \vert Im ( {Z}_{nex = i , bval , bvec = {v}_{j}} ) \vert ) & ( 6 )\end{matrix}$$

$$\begin{matrix}[ Equation 7 ] & \\ {Corr}_{bval} = Smooth ( \vert \frac{1}{V} {\sum }_{j = 1}^{V} \frac{1}{N} {\sum }_{i = 1}^{N} Im ( {Z}_{nex = i , bval , bvec = {v}_{j}} ) \vert ) & ( 7 )\end{matrix}$$

In Equation (6) described above, the correction value Corr_{bval} is calculated by calculating an absolute value of a value (Im(Z_{nex=i,bval,bvec=vj}) of an imaginary component included in the complex image Z with the MPG intensity bval and MPG direction bvec=vj for the i-th acquisition out of the number of image acquisitions nex, then performing averaging from first to Nth acquisitions out of the number of image acquisitions nex, and then performing averaging by the number of MPG axes along which the complex image Z has been captured. That is, in Equation (6) described above, the correction value Corr is calculated by first performing the calculation of an absolute value of a noise value of Gaussian noise of pixels at the same position corresponding to the average value Avg of a signal of interest in a plurality of complex images Z, and then performing two types of averaging. In the correction value Corr calculated by Equation (6) described above, averaging is performed with all noise values of Gaussian noise being positive values. Thus, the correction value Corr becomes a value larger than the correction value Corr calculated by Equation (3) described above. For this reason, in a diffusion-weighted image generated by the image generation function 536, a pixel value at a position where the pixel value is corrected (replaced) becomes larger than that in a diffusion-weighted image generated by correcting (replacing) a pixel value using the correction value Corr calculated by Equation (3) described above, and a medical image containing noticeable noise is obtained. In other words, a diffusion-weighted image generated by correcting (replacing) a pixel value using the correction value Corr calculated by Equation (6) described above becomes a medical image close to a diffusion-weighted image generated by the conventional configuration in which real part addition by removal of background phase is performed.

The calculation of the correction value Corr by Equation (6) described above is an example of a “second calculation method”.

On the other hand, in Equation (7) described above, the correction value Corr_{bval} is calculated by averaging values (Im(Z_{nex=i,bval,bvec=vj})) of an imaginary component included in the complex image Z with the MPG intensity bval and MPG direction bvec=vj for the i-th acquisition out of the number of image acquisitions nex, from first to Nth acquisitions out of the number of image acquisitions nex, and further performing averaging by the number of MPG axes along which the complex image Z has been captured, and then calculating an absolute value. That is, in Equation (7) described above, the correction value Corr is calculated by performing two types of averaging on noise values of Gaussian noises of pixels at the same position corresponding to the average value Avg of a signal of interest in a plurality of complex images Z, and then lastly performing the calculation of an absolute value. In the correction value Corr calculated by Equation (7) described above, all noise values of Gaussian noise containing positive and negative values are averaged, become a value close to “0, and then become a positive value. Thus, the correction value Corr becomes a value smaller than the correction value Corr calculated by Equation (3) described above. For this reason, in a diffusion-weighted image generated by the image generation function 536, a pixel value at a position where the pixel value is corrected (replaced) becomes smaller than that in a diffusion-weighted image generated by correcting (replacing) a pixel value using the correction value Corr calculated by Equation (3) described above, and a medical image in which noise is corrected (removed) more naturally (without causing a sense of incongruity) is obtained.

The calculation of the correction value Corr by Equation (7) described above is an example of a “first calculation method”.

The image generation function 536 may be configured to switch a correction value to any of the correction values Corr calculated by Equation (3) described above, Equation (6) described above, and Equation (7) described above when generating a diffusion-weighted image while correcting a background-phase-removed complex image output by the background phase removal function 534. That is, the image generation function 536 may be configured to change the strength of correction of a background-phase-removed complex image that is to be performed when a diffusion-weighted image is generated, for each diffusion-weighted image to be generated. The image generation function 536 may also be configured to change the strength of correction of a background-phase-removed complex image that is to be performed when a diffusion-weighted image is generated, for each pixel included in the same diffusion-weighted image. Here, the strength of correction becomes stronger in order of Equation (7) described above, Equation (3) described above, and Equation (6) described above.

### [Yet Another Example of Correction Value]

In the above-described examples (including another example), the correction value Corr is calculated using Gaussian noise for each MPG intensity bval, but the correction value Corr may be calculated for each MPG intensity bval and each MPG direction bvec, similarly to the average value Avg. The calculation of the correction value Corr to be performed in such cases is represented by Equation (8) described below or Equation (9) described below. Also when the correction value Corr_{bval,bvec} is calculated by Equation (8) described below or Equation (9) described below, smoothing may be omitted, but for the sake of ease of comparison with Equation (3) described above, Equation (6) described above, and Equation (7) described above, in Equation (8) described below and Equation (9) described below, an example in a case where smoothing is performed is described. Nevertheless, also in the following description, for the sake of ease of description of the timing of the calculation of an absolute value, the description of smoothing is omitted.

$$\begin{matrix}[ Equation 8 ] & \\ {Corr}_{bval , bvec} = Smooth ( \vert \frac{1}{N} {\sum }_{i = 1}^{N} Im ( {Z}_{nex = i , bval , bvec} ) \vert ) & ( 8 )\end{matrix}$$

$$\begin{matrix}[ Equation 9 ] & \\ {Corr}_{bval , bvec} = Smooth ( \frac{1}{N} {\sum }_{i = 1}^{N} \vert Im ( {Z}_{nex = i , bval , bvec} ) \vert ) & ( 9 )\end{matrix}$$

In Equation (8) described above, the correction value Corr_{bval,bvec} is calculated by averaging values (Im(Z_{nex=i,bval,bvec})) of an imaginary component included in the complex image Z with the MPG intensity bval and the MPG direction bvec for the i-th acquisition out of the number of image acquisitions nex, from first to Nth acquisitions out of the number of image acquisitions nex, and then calculating an absolute value.

On the other hand, in Equation (9) described above, the correction value Corr_{bval,bvec} is calculated by calculating an absolute value of a value (Im(Z_{nex=i,bval,bvec})) of an imaginary component included in the complex image Z with the MPG intensity bval and the MPG direction bvec for the i-th acquisition out of the number of image acquisitions nex, and then performing averaging from first to Nth acquisitions out of the number of image acquisitions nex.

The image generation function 536 generates a diffusion-weighted image while correcting a background-phase-removed complex image output by the background phase removal function 534, when a diffusion-weighted image is generated, using the correction value Corr_{bval,bvec} calculated by Equation (8) described above or Equation (9) described above. Also in this case, a diffusion-weighted image generated by the image generation function 536 becomes a medical image that appears natural and does not cause a sense of incongruity, compared with a diffusion-weighted image conventionally generated by averaging complex images on which real part addition by removal of background phase has been performed.

The image generation function 536 may be configured to switch a correction value to any of the correction values Corr calculated by Equation (8) described above and Equation (9) described above, when generating a diffusion-weighted image while correcting a background-phase-removed complex image output by the background phase removal function 534. That is, even in the case of calculating the correction value Corr for each MPG intensity bval and each MPG direction bvec, the image generation function 536 may be configured to change the strength of correction of a background-phase-removed complex image that is performed when a diffusion-weighted image is generated, for each pixel. Here, the strength of correction becomes stronger in order of Equation (8) described above and Equation (9) described above.

As described above, in the medical image processing apparatus according to the embodiment, similarly to the conventional configuration in which real part addition by removal of background phase is performed, the image processing function 53 generates a complex image (background-phase-removed complex image). Then, in the medical image processing apparatus according to the embodiment, the image processing function 53 generates a diffusion-weighted image while correcting, using a pixel value of a pixel in an imaginary image that is conventionally discarded (background-phase-removed imaginary image containing only Gaussian noise), a pixel in a real image (background-phase-removed real image) in which the signal intensity (level) of a signal of interest is lower than a predetermined level. With this configuration, in the medical image diagnosis apparatus (the MRI apparatus 1) including the medical image processing apparatus according to the embodiment, it is possible to improve the state of noise contained in each original complex image generated by averaging, and display a diffusion-weighted image that appears natural and does not cause a sense of congruity compared to a diffusion-weighted image conventionally generated by averaging complex images on which real part addition by removal of background phase has been performed, on the display 42 and present the diffusion-weighted image to an MRI examination personnel. The MRI examination personnel can accordingly visually check the presented diffusion-weighted image (MR image), and naturally perform diagnosis or examination to determine whether the subject P has a lesion, or the like.

In the above-described embodiment, the image processing function 53 removes a background phase component included in a complex image, similarly to the conventional configuration in which real part addition by removal of background phase is performed, and corrects a pixel of a real component of the complex image using a noise value of Gaussian noise of an imaginary component included in the complex image from which the background phase component has been removed. Nevertheless, a noise value for correcting the pixel of the real component of the complex image is not limited to a noise value of an imaginary component of the complex image from which the background phase component has been removed, and the pixel of the real component of the complex image may be corrected using a value of noise that can be estimated by applying various methods to a captured image. The image processing function 53 may correct the pixel of the real component of the complex image using a value of noise that can be estimated from various MR images to be captured by the MRI apparatus 1 (noise unique to the MRI apparatus 1), such as a geometry-Factor (g-Factor) or a sensitivity map, for example. The MR images to be used for estimation of the noise in this case are not limited to captured images (complex images) of the subject P to be examined (image capturing target) in this MRI examination, and may be captured images of a different subject in which a similar image capturing region is captured, for example, or may be images captured in a state in which a subject is not placed on the couchtop 24. That is, MR images to be used for the estimation of the noise are not limited to images captured in this MRI examination, and may be images of a different subject or images captured at a different time. Functional configurations, operations, processing, and the like of the image processing function 53 in such cases can be easily considered based on functional configurations, operations, processing, and the like of the image processing function 53 in the processing circuitry 50 included in the MRI apparatus 1 according to the above-described embodiment. Accordingly, detailed description of the functional configurations, operations, processing, and the like of the image processing function 53 in the case of correcting a pixel of a real component of a complex image using a value other than a value of noise of an imaginary component of the complex image from which the background phase component has been removed is omitted.

In the above-described embodiment, the description has been provided of a case where a medical image processing apparatus is included in the MRI apparatus 1, and the image processing function 53 in the medical image processing apparatus generates a diffusion-weighted image based on a complex image captured by the MRI apparatus 1. Nevertheless, a medical image to be generated by the medical image processing apparatus is not limited to a diffusion-weighted image. As long as the image is generated by performing magnitude conversion processing on a complex image, a similar concept as that of the medical image processing apparatus (image processing function 53) according to the above-described embodiment can be applied to generation processing of any medical image, and a medical image that appears more natural (and does not cause a sense of incongruity) and in which the state of noise is improved can be similarly generated.

In the above-described embodiment, in the image processing function 53 (more specifically, the background phase removal function 534), an example of a case in which a background phase component is removed by representing all signal intensities (levels) of a signal of interest as complex signals on the real axis R by setting the background phase component θ to “0°” has been described (see FIG. 3C). Nevertheless, the method of removing a background phase component is not limited to the method of setting the background phase component θ to “0°”. For example, the background phase removal function 534 may remove a background phase component by representing all signal intensities (levels) of a signal of interest as complex signals on the imaginary axis I by setting the background phase component θ to “90°. That is, the background phase removal function 534 may represent all the signal intensities (levels) of a signal of interest on either the real axis R or the imaginary axis I, and remove the other of the real axis R and the imaginary axis I as the background phase component. Functional configurations, operations, processing, and the like of the image processing function 53 in such cases can be easily considered by swapping a real component and an imaginary component in the functional configurations, operations, processing, and the like of the image processing function 53 in the processing circuitry 50 included in the MRI apparatus 1 according to the above-described embodiment. Accordingly, detailed description of the functional configurations, operations, processing, and the like of the image processing function 53 in the case of removing the background phase component θ by representing all the signal intensities (levels) of a signal of interest as a complex signal on the imaginary axis I is omitted.

In the above-described embodiment, a case where a medical image processing apparatus is included in a magnetic resonance imaging apparatus (the MRI apparatus 1) has been described as an example, but this is merely an example. As long as the medical image processing apparatus is a medical image diagnosis apparatus that generates a medical image by performing processing on a complex signal (complex image) (handles a complex signal), any medical image diagnosis apparatus may be used. For example, the medical image diagnosis apparatus may be an ultrasonic diagnosis apparatus that captures a complex signal (complex image). Also in this case, the medical image processing apparatus can generate a medical image that appears more natural and does not cause a sense of incongruity and in which the state of noise is improved. The configurations, operations, and processing of the medical image processing apparatus in such a case may be changed to configurations, operations, and processing suitable for a medical image diagnosis apparatus (e.g., ultrasonic diagnosis apparatus) including a medical image processing apparatus so as to be equivalent to the configurations, operations, and processing of the medical image processing apparatus according to the above-described embodiment. Accordingly, the detailed description of the configurations, operations, and processing of a medical image processing apparatus included in a medical image diagnosis apparatus other than an MRI apparatus is omitted.

The embodiment described above can be expressed as follows.

A medical image processing apparatus that generates a medical image based on a first complex image obtained by capturing an image of a subject, the medical image processing apparatus comprising:
processing circuitry configured to generate a second complex image obtained by removing a component of background phase from the first complex image, and generate the medical image by correcting, using noise contained in the second complex image, a pixel value of a first pixel in which a pixel value of a signal of interest representing an image of the subject is equal to or smaller than zero, in each pixel included in the second complex image.

According to at least one embodiment described above, a medical image processing apparatus (53) configured to generate a medical image (diffusion-weighted image) based on a first complex image (CI) obtained by capturing an image of a subject (P), comprises an image generation unit (535) configured to generate a second complex image (RCI) obtained by removing a component of background phase from the first complex image, and generate the medical image by correcting, using noise (Gaussian noise) contained in the second complex image, a pixel value of a first pixel in which a pixel value of a signal of interest representing an image of the subject is equal to or smaller than zero, in each pixel included in the second complex image, thereby enabling correction of a value of a pixel with low signal intensity into a state suitable for image processing, in the medical image processing apparatus that performs image processing for generating the medical image using the complex image obtained by capturing the image of the subject.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A medical image processing apparatus that generates a medical image based on a first complex image obtained by capturing an image of a subject, the medical image processing apparatus comprising processing circuitry configured to:
generate a second complex image obtained by removing a component of background phase from the first complex image, and generate the medical image by correcting, using noise contained in the second complex image, a pixel value of a first pixel in which a pixel value of a signal of interest representing an image of the subject is equal to or smaller than zero, in each pixel included in the second complex image.

2. The medical image processing apparatus according to claim 1,
wherein the processing circuitry generates the second complex image in which the signal of interest represented by a real component and an imaginary component in the first complex image is represented entirely by either the real component or the imaginary component, and
wherein the processing circuitry generates the medical image by correcting, for each pixel included in a first component image represented by the other of the real component or the imaginary component of the second complex image, a pixel value of the first pixel using a noise value of the noise represented by a second pixel at a same position as the first pixel, the second pixel being included in a second component image represented by either a real component or an imaginary component of the second complex image.

3. The medical image processing apparatus according to claim 2,
wherein the medical image is a medical image generated by averaging a plurality of second component images,
wherein the processing circuitry calculates an average value obtained by averaging a pixel value of the first pixel at a same position in a plurality of second component images as a pixel value indicating the signal of interest in a pixel included in the medical image,
wherein the processing circuitry calculates a value obtained by averaging the noise value indicated by the second pixel at a same position in a plurality of first component images as a correction value for correcting the average value, and
wherein, in a case where the correction value at a same position is larger than the average value, the processing circuitry corrects the pixel value of the first pixel by replacing the average value with the correction value.

4. The medical image processing apparatus according to claim 3,
wherein the noise is noise containing a positive noise value and a negative noise value,
wherein calculation of the correction value includes calculation of an absolute value of a noise value of the noise indicated by the second pixel, and
wherein the processing circuitry switches a timing at which the correction value is calculated in the calculation of the correction value.

5. The medical image processing apparatus according to claim 4,
wherein the calculation of the correction value includes:
a first calculation method of performing calculation of the absolute value after averaging the noise value indicated by the second pixel at the same position in the plurality of first component images; and
a second calculation method of performing the calculation of the absolute value on the noise value indicated by the second pixel at a same position in each of the first component images, and then averaging calculation results of the absolute value, and
wherein the processing circuitry switches between the first calculation method and the second calculation method in the calculation of the correction value.

6. The medical image processing apparatus according to claim 1,
wherein the medical image is a diffusion-weighted image generated by a magnetic resonance imaging apparatus, and
wherein the processing circuitry generates a plurality of second complex images respectively corresponding to a plurality of first complex images captured while varying an intensity and a direction of a gradient magnetic field in the magnetic resonance imaging apparatus, and generates the medical image by correcting the pixel value of the first pixel using noise contained in each of the second complex images.

7. A medical image processing method executed by a computer of a medical image processing apparatus that generates a medical image based on a first complex image obtained by capturing an image of a subject, the medical image processing method comprising:
generating a second complex image obtained by removing a component of background phase from the first complex image; and
generating the medical image by correcting, using noise contained in the second complex image, a pixel value of a first pixel in which a pixel value of a signal of interest representing an image of the subject is equal to or smaller than zero, in each pixel included in the second complex image.

8. A non-transitory computer-readable storage medium storing a program for causing a computer of a medical image processing apparatus that generates a medical image based on a first complex image obtained by capturing an image of a subject to:
generate a second complex image obtained by removing a component of background phase from the first complex image; and
generate the medical image by correcting, using noise contained in the second complex image, a pixel value of a first pixel in which a pixel value of a signal of interest representing an image of the subject is equal to or smaller than zero, in each pixel included in the second complex image.
